(19) United States
(12) Patent Application Publication
(10) Pub. No.: US 2026/0138926 A1
(43) Pub. Date: May 21, 2026

(54) LOW-TEMPERATURE FIRED CERAMIC AND ELECTRONIC COMPONENT

(71) Applicant: Murata Manufacturing Co, Ltd., Nagaokakyo-shi (JP)

(72) Inventors: Satoru ADACHI, Nagaokakyo-shi (JP); Yasutaka SUGIMOTO, Nagaokakyo-shi (JP); Sadaaki SAKAMOTO, Nagaokakyo-shi (JP); Tamami MORIMOTO, Nagaokakyo-shi (JP); Taichi WATANABE, Nagaokakyo-shi (JP)

(21) Appl. No.: 19/448,558

(22) Filed: Jan. 14, 2026

Related U.S. Application Data
(63) Continuation of application No. PCT/JP2024/024214, filed on Jul. 4, 2024.

(30) Foreign Application Priority Data
Jul. 28, 2023 (JP) 2023-123476
Dec. 28, 2023 (JP) 2023-222867

(51) Int. Cl. C04B 35/14; B32B 18/00; C03C 14/00; C04B 35/195; C04B 35/468; H01F 17/00; H01G 4/12; H03H 1/00

(52) U.S. Cl. CPC C04B 35/14; B32B 18/00; C03C 14/004; C04B 35/195; C04B 35/4686; C03C 2214/04; C04B 2235/3222; C04B 2235/3232; C04B 2235/3236; C04B 2235/3281; C04B 2235/3418; C04B 2235/3427; C04B 2235/3481; C04B 2235/365; C04B 2235/407; H01F 17/0013; H01F 2017/0026; H01G 4/1227; H03H 1/00; H03H 2001/0085

(57) ABSTRACT

A low-temperature fired ceramic that contains a fired glass component represented by RO—ZnO—Al₂O₃—B₂O₃—SiO₂, wherein RO is at least one selected from the group consisting of MgO, CaO, SrO, and BaO, a percentage of RO, a percentage of ZnO, and a percentage of Al₂O₃ in the fired glass component are each 0.1 mol % to 10 mol %, a sum of the percentage of RO, the percentage of ZnO, and the percentage of Al₂O₃ in the fired glass component is 15 mol % or less, and a ratio of a percentage of SiO₂ to a percentage of B₂O₃ (SiO₂/B₂O₃) in the fired glass component is less than 3.4; and one or more oxides of ceramic crystalline components that include at least one selected from the group consisting of SiO₂, BaAl₂Si₂O₈, ZnAl₂O₄, and Zn₂SiO₄.

### CROSS REFERENCE TO RELATED APPLICATIONS

The present application is a continuation of International application No. PCT/JP2024/024214, filed Jul. 4, 2024, which claims priority to Japanese Patent Application No. 2023-123476, filed Jul. 28, 2023, and Japanese Patent Application No. 2023-222867, filed Dec. 28, 2023, the entire contents of each of which are incorporated herein by reference.

### TECHNICAL FIELD

The present disclosure relates to a low-temperature fired ceramic and an electronic component.

### BACKGROUND ART

Known ceramic materials for ceramic multilayer wiring boards include a glass ceramic material (LTCC material) that can be fired at a low temperature.

For example, Patent Literature 1 discloses a glass composition to reduce the dielectric loss (dissipation factor) of glass ceramics for LTCC substrates to less than 20×10⁻⁴ in GHz-order frequency ranges. Specifically, Patent Literature 1 discloses a glass composition for a low-temperature fired substrate having a basic composition represented by RO—Al₂O₃—B₂O₃—SiO₂ (RO is one or more selected from the group consisting of MgO, CaO, SrO, BaO, and ZnO), wherein RO and Al₂O₃ are each in the range of 1 to 25 mol %, and the molar percent ratio of SiO₂/B₂O₃ is 1.3 or less. Patent Literature 1 also discloses a glass ceramic containing a filler in the glass composition for a low-temperature fired substrate.
Patent Literature 1: JP 2004-26529 A

### SUMMARY OF THE DISCLOSURE

A reduction in dielectric loss of glass ceramics requires a reduction in the amount of the modifiers RO and Al₂O₃ in glass in the fired body obtained by firing. Patent Literature 1 only specifies that the glass before firing has a composition in which both RO and Al₂O₃ are 25 mol % or less, and does not specify the composition of the fired body obtained by firing. Patent Literature 1 is thus silent about how to reduce the dielectric loss to less than 16×10⁻⁴.

Based on the above matter, the present disclosure aims to provide a low-temperature fired ceramic with a small dielectric loss.

A first low-temperature fired ceramic of the present disclosure contains: a fired glass component represented by RO—ZnO—Al₂O₃—B₂O₃—SiO₂, wherein RO is at least one selected from the group consisting of MgO, CaO, SrO, and BaO, a percentage of RO, a percentage of ZnO, and a percentage of Al₂O₃ in the fired glass component are each 0.1 mol % to 10 mol %, a sum of the percentage of RO, the percentage of ZnO, and the percentage of Al₂O₃ in the fired glass component is 15 mol % or less, and a ratio of a percentage of SiO₂ to a percentage of B₂O₃ (SiO₂/B₂O₃) in the fired glass component is less than 3.4; and one or more oxides of ceramic crystalline components that include at least one selected from the group consisting of SiO₂, BaAl₂Si₂O₈, ZnAl₂O₄, and Zn₂SiO₄.

A second low-temperature fired ceramic of the present disclosure contains: a fired glass component represented by RO—ZnO—Al₂O₃—B₂O₃—SiO₂, wherein RO is at least one selected from the group consisting of MgO, CaO, SrO, and BaO, a percentage of RO, a percentage of ZnO, and a percentage of Al₂O₃ in the fired glass component are each 0.1 mol % to 10 mol %, and a sum of the percentage of RO, the percentage of ZnO, and the percentage of Al₂O₃ in the fired glass component is 15 mol % or less; and one or more oxides of ceramic crystalline components include at least one selected from the group consisting of Ba₂Ti₉O₂₀, BaTi(BO₃)₂, BaTi₄O₉, BaTi₅O₁₁, Ba₄Ti₁₃O₃₀, BaZn₂Ti₄O₁₁, and Ba₄ZnTi₁₁O₂₇.

A first electronic component of the present disclosure includes the first low-temperature fired ceramic or second low-temperature fired ceramic of the present disclosure.

A second electronic component of the present disclosure includes a low-permittivity ceramic layer containing a first low-temperature fired ceramic; and a high-permittivity ceramic layer containing a second low-temperature fired ceramic, the high-permittivity ceramic layer having a permittivity greater than the low-permittivity ceramic layer, wherein the first low-temperature fired ceramic contains a first fired glass component and one or more first oxides of ceramic crystalline components, the second low-temperature fired ceramic contains a second fired glass component and one or more second oxides of ceramic crystalline components, the first fired glass component and the second fired glass component are represented by RO—ZnO—Al₂O₃—B₂O₃—SiO₂, RO is at least one selected from the group consisting of MgO, CaO, SrO, and BaO, a percentage of RO, a percentage of ZnO, and a percentage of Al₂O₃ in the first fired glass component and a percentage of RO, a percentage of ZnO, and a percentage of Al₂O₃ in the second fired glass component are each 0.1 mol % to 10 mol %, and a sum of the percentage of RO, the percentage of ZnO, and the percentage of Al₂O₃ in the first fired glass component and a sum of the percentage of RO, the percentage of ZnO, and the percentage of Al₂O₃ in the second fired glass component are each 15 mol % or less, a ratio of a percentage of SiO₂ to a percentage of B₂O₃ (SiO₂/B₂O₃) in the first fired glass component is less than 3.4, the first low-temperature fired ceramic further contains Al₂O₃ in addition to the Al₂O₃ contained in the first fired glass component, and a percentage of the Al₂O₃ in the first low-temperature fired ceramic, excluding the Al₂O₃ contained in the fired glass component, is more than 0 wt % and 5 wt % or less, the one or more first oxides of the ceramic crystalline components include BaAl₂Si₂O₈ and at least two selected from the group consisting of SiO₂, ZnAl₂O₄, Zn₂SiO₄, and TiO₂, a percentage of BaAl₂Si₂O₈ in the first low-temperature fired ceramic is more than 0 wt % and 5 wt % or less, and the one or more second oxides of the ceramic crystalline components include at least one selected from the group consisting of Ba₂Ti₉O₂₀, BaTi(BO₃)₂, BaTi₄O₉, BaTi₅O₁₁, Ba₄Ti₁₃O₃₀, BaZn₂Ti₄O₁₁, and Ba₄ZnTi₁₁O₂₇.

The present disclosure can provide a low-temperature fired ceramic with a small dielectric loss.

### BRIEF DESCRIPTION OF THE DRAWINGS

FIG. 1 is a schematic cross-sectional view of an example of a multilayer ceramic electronic component as a first electronic component of the present disclosure.

FIG. 2 is a schematic cross-sectional view of a multilayer green sheet (in an unfired state) produced during the production process of the multilayer ceramic electronic component in FIG. 1.

FIG. 3 is a schematic cross-sectional view of an example of a multilayer ceramic electronic component as a second electronic component of the present disclosure.

FIG. 4 is a schematic cross-sectional view of a multilayer green sheet (in an unfired state) produced during the production process of the multilayer ceramic electronic component in FIG. 3.

### DESCRIPTION OF THE PREFERRED EMBODIMENTS

The low-temperature fired ceramics and the electronic components of the present disclosure are described below. The present disclosure is not limited to the following preferred embodiments and may be suitably modified without departing from the gist of the present disclosure. Combinations of two or more preferred features described in the following preferred features are also within the scope of the present disclosure.

The low-temperature fired ceramics of the present disclosure are each a fired body obtained by firing a low-temperature co-fired ceramic (LTCC) material, which is a glass ceramic material that can be sintered at a firing temperature of 1000° C. or lower.

The low-temperature fired ceramics of the present disclosure herein include a first low-temperature fired ceramic and a second low-temperature fired ceramic. As described later, the first low-temperature fired ceramic is a low-temperature fired ceramic with low permittivity (low-permittivity ceramic), and the second low-temperature fired ceramic is a low-temperature fired ceramic with high permittivity (high-permittivity ceramic). Hereinafter the first low-temperature fired ceramic may be referred to as a low-temperature fired ceramic with low permittivity or a low-permittivity ceramic. Hereinafter the second low-temperature fired ceramic may be referred to as a low-temperature fired ceramic with high permittivity or a high-permittivity ceramic. Herein, the low-permittivity ceramic has a relative permittivity of 7 or less, and the high-permittivity ceramic has a relative permittivity of more than 7.

### First Low-Temperature Fired Ceramic

The first low-temperature fired ceramic of the present disclosure contains a fired glass component (A1) and one or more oxides of ceramic crystalline components (C1).

The fired glass component (A1) is represented by RO—ZnO—Al₂O₃—B₂O₃—SiO₂, and RO is at least one selected from the group consisting of MgO, CaO, SrO, and BaO. RO is an alkaline earth metal oxide.

The percentage of RO, the percentage of ZnO, and the percentage of Al₂O₃ in the fired glass component (A1) are each 0.1 mol % to 10 mol %, and the sum of the percentage of RO, the percentage of ZnO, and the percentage of Al₂O₃ in the fired glass component (A1) is 15 mol % or less.

In the first low-temperature fired ceramic of the present disclosure, the percentage of RO, the percentage of ZnO, and the percentage of Al₂O₃ in the fired glass component (A1) are specified to be low, which results in a low-temperature fired ceramic with a small dielectric loss.

Among the components of the first low-temperature fired ceramic, the fired glass component (A1) has a large dielectric loss, and the one or more oxides of the ceramic crystalline components (C1) have a small dielectric loss. The dielectric loss of the fired glass component (A1) is dominant over the dielectric loss of the first low-temperature fired ceramic, so that it is important to reduce the dielectric loss of the fired glass component (A1). Thus, the percentage of RO, the percentage of ZnO, and the percentage of Al₂O₃ in the fired glass component (A1) are specified to be low, so that the dielectric loss of the first low-temperature fired ceramic is reduced.

The low-temperature co-fired ceramic (LTCC) material contains RO, ZnO, and Al₂O₃ in the glass component before firing. The RO, ZnO, and Al₂O₃ precipitate from the glass when fired, which reduces the percentage of RO, the percentage of ZnO, and the percentage of Al₂O₃ in the fired glass component. Precipitation of RO, ZnO, and Al₂O₃ from the glass by firing results in a low-temperature fired ceramic with a small dielectric loss.

The percentage of RO in the fired glass component (A1) is preferably 0.3 mol % to 6.0 mol %, more preferably 0.4 mol % to 5.5 mol %.

The percentage of ZnO in the fired glass component (A1) is preferably 0.5 mol % to 6.0 mol %, more preferably 2.0 mol % to 5.5 mol %.

The percentage of Al₂O₃ in the fired glass component (A1) is preferably 0.5 mol % to 9.5 mol %, more preferably 1.0 mol % to 9.5 mol %.

The sum of the percentage of RO, the percentage of ZnO, and the percentage of Al₂O₃ in the fired glass component (A1) is for example 1.0 mol % or more, preferably 5.0 mol % or more.

The percentage of RO (alkaline earth metal oxide), the percentage of ZnO, and the percentage of Al₂O₃ in the fired glass component (A1) can be obtained by measuring the first low-temperature fired ceramic (fired body) by powder X-ray diffraction (XRD measurement) at a low scanning rate of 0.2 deg/min and determining the composition of the glass component by Rietveld analysis.

When measuring a fired body sample of a commercial product, a glass area of an exfoliated sample is identified by STEM and electron diffraction, and the glass area is measured by wavelength dispersive X-ray analysis (WDS), whereby the composition of the glass component can be determined. The crystal phase that is present can be identified by electron diffraction.

Preferably, the fired glass component (A1) contains no alkali metal oxide. With the fired glass component (A1) containing no alkali metal oxide, a low-temperature fired ceramic with a small dielectric loss can be obtained. When the fired glass component (A1) contains an alkali metal oxide, the percentage of the alkali metal oxide in the fired glass component (A1) is preferably 0.1 mol % or less.

RO is preferably BaO. The presence of BaO in the composition of the fired glass component (A1) can reduce the dielectric loss.

Preferred percentages of RO, ZnO, Al₂O₃, B₂O₃, and SiO₂ in the fired glass component (A1) are as follows.
RO: 0.1 mol % to 10 mol %
ZnO: 0.1 mol % to 10 mol %
Al₂O₃: 0.1 mol % to 10 mol %
B₂O₃: 20 mol % to 45 mol %
SiO₂: 45 mol % to 70 mol %

The ratio of the percentage of SiO₂ to the percentage of B₂O₃ (SiO₂/B₂O₃) in the fired glass component (A1) is less than 3.4. A ratio of the percentage of SiO₂ to the percentage of B₂O₃ of 3.4 or higher may cause sintering failure, reducing the Q-factor of the first low-temperature fired ceramic. The ratio of the percentage of SiO₂ to the percentage of B₂O₃ is preferably less than 3.3, more preferably less than 3.1. The ratio of the percentage of SiO₂ to the percentage of B₂O₃ is preferably 1.4 or more.

In the first low-temperature fired ceramic, the one or more oxides of the ceramic crystalline components (C1) include at least one selected from the group consisting of SiO₂, BaAl₂Si₂O₈, ZnAl₂O₄, and Zn₂SiO₄. Since none of these oxides have high permittivity, the permittivity of the first low-temperature fired ceramic can be adjusted to 7 or less. SiO₂ as one of the oxides of the ceramic crystalline components (C1) can be distinguished from SiO₂ contained in the fired glass component (A1).

In the low-permittivity ceramic, the one or more oxides of the ceramic crystalline components (C1) preferably further include TiO₂. The glass component, SiO₂, BaAl₂Si₂O₈, ZnAl₂O₄, and Zn₂SiO₄ characteristically show an increase in permittivity with increasing temperature. TiO₂, which characteristically shows a decrease in permittivity with increasing temperature, can adjust the characteristics of the first low-temperature fired ceramic such that the permittivity is less affected by temperature.

Preferred percentages of SiO₂, BaAl₂Si₂O₈, ZnAl₂O₄, Zn₂SiO₄, and TiO₂ as the oxides of the ceramic crystalline components (C1) of the low-permittivity ceramic are as follows.
SiO₂: 0 wt % to 50 wt %
BaAl₂Si₂O₈: 0 wt % to 30 wt %
ZnAl₂O₄: 0 wt % to 30 wt %
Zn₂SiO₄: 0 wt % to 25 wt %
TiO₂: 0.1 wt % to 10 wt %

The one or more oxides of the ceramic crystalline components (C1) in the low-permittivity ceramic preferably include BaAl₂Si₂O₈ and at least two selected from the group consisting of SiO₂, ZnAl₂O₄, Zn₂SiO₄, and TiO₂. As described later, a sheet of the low-temperature fired ceramic with low permittivity and a sheet of the low-temperature fired ceramic with high permittivity may be stacked, compression-bonded, and co-sintered to produce a co-sintered body. In such a case, the above composition of the oxides of the ceramic crystalline components leads to less reaction between the materials or less difference in shrinkage behavior between the materials during firing, thus reducing defects such as delamination.

The percentage of BaAl₂Si₂O₈ in the low-permittivity ceramic is preferably more than 0 wt % and 5 wt % or less. The percentage of BaAl₂Si₂O₈ within the range can further reduce the temperature coefficient of capacitance (TCC). The percentage of BaAl₂Si₂O₈ is more preferably more than 0.1 wt % and 3 wt % or less.

BaAl₂Si₂O₈ has the effect of increasing the TCC of low-temperature fired ceramics positively, while TiO₂ has the effect of increasing the TCC of low-temperature fired ceramics negatively. The TCC of low-temperature fired ceramics can be adjusted by adjusting the amounts of BaAl₂Si₂O₈ and TiO₂ blended. When the low-permittivity ceramic is prepared, the TCC is preferably adjusted by decreasing the amount of BaAl₂Si₂Og blended because increasing the amount of TiO₂ increases the relative permittivity. The percentage of BaAl₂Si₂Og in the low-permittivity ceramic, particularly when the low-permittivity ceramic contains no TiO₂, is preferably more than 0 wt % and 5 wt % or less.

Preferably, the low-permittivity ceramic further contains Al₂O₃ in addition to Al₂O₃ contained in the fired glass component (A1), and the percentage of Al₂O₃ in the low-temperature fired ceramic, excluding Al₂O₃ contained in the fired glass component (A1), is preferably more than 0 wt % and 5 wt % or less. When the percentage of Al₂O₃ in the low-temperature fired ceramic, excluding Al₂O₃ contained in the fired glass component (A1), is more than 5 wt %, defects such as pores or cracks may occur in the co-sintered body produced by stacking, compression-bonding, and co-sintering a sheet of the low-temperature fired ceramic with low permittivity and a sheet of the low-temperature fired ceramic with high permittivity. Al₂O₃ contained in the fired glass component (A1) can be distinguished from other Al₂O₃.

### Second Low-Temperature Fired Ceramic

The second low-temperature fired ceramic of the present disclosure contains a fired glass component (A2) and one or more oxides of ceramic crystalline components (C2).

The fired glass component (A2) is the same as the fired glass component (A1), except that the fired glass component (A2) is not limited in the ratio of the percentage of SiO₂ to the percentage of B₂O₃.

In the second low-temperature fired ceramic (high-permittivity ceramic), the one or more oxides of the ceramic crystalline components (C2) include at least one selected from the group consisting of Ba₂Ti₉O₂₀, BaTi(BO₃)₂, BaTi₄O₉, BaTi₅O₁₁, Ba₄Ti₁₃O₃₀, BaZn₂Ti₄O₁₁, and Ba₄ZnTi₁₁O₂₇. All these oxides have high permittivity and allow the fired body to have a permittivity of more than 7.

In one embodiment of the one or more oxides of the ceramic crystalline components (C2) in the high-permittivity ceramic, the sum of the percentage of Ba₂Ti₉O₂₀ and the percentage of BaTi(BO₃)₂ is preferably 5 wt % or more, more preferably 30 wt % or more, still more preferably 40 wt % or more. The sum of the percentage of Ba₂Ti₉O₂₀ and the percentage of BaTi(BO₃)₂ is preferably 90 wt % or less, for example. The high-permittivity ceramic may be free of Ba₂Ti₉O₂₀ and BaTi(BO₃)₂.

Ba₂Ti₉O₂₀ and BaTi(BO₃)₂ show little change in permittivity even with increasing temperature.

In one embodiment of the one or more oxides of the ceramic crystalline components (C2) in the high-permittivity ceramic, the sum of the percentage of Ba₂Ti₉O₂₀, the percentage of BaTi(BO₃)₂, the percentage of BaTi₄O₉, the percentage of BaTi₅O₁₁, the percentage of Ba₄Ti₁₃O₃₀, the percentage of BaZn₂Ti₄O₁₁, and the percentage of Ba₄ZnTi₁O₂₇ is preferably 5 wt % or more, more preferably 30 wt % or more, still more preferably 40 wt % or more. The sum of the percentage of Ba₂Ti₉O₂₀, the percentage of BaTi(BO₃)₂, the percentage of BaTi₄O₉, the percentage of BaTi₅O₁₁, the percentage of Ba₄Ti₁₃O₃₀, the percentage of BaZn₂Ti₄O₁₁, and the percentage of Ba₄ZnTi₁₁O₂₇ is preferably 90 wt % or less, for example.

The percentage of Ba₂Ti₉O₂₀, the percentage of BaTi(BO₃)₂, the percentage of BaTi₄O₉, the percentage of BaTi₅O₁₁, the percentage of Ba₄Ti₁₃O₃₀, the percentage of BaZn₂Ti₄O₁₁, and the percentage of Ba₄ZnTi₁₁O₂₇ in the high-permittivity ceramic can be obtained by measuring the high-permittivity ceramic (fired body) by powder X-ray diffraction (XRD measurement) in the same manner as for the percentage of alkaline earth metal oxide (RO) in the fired glass component.

The one or more oxides of the ceramic crystalline components (C2) in the high-permittivity ceramic preferably further include at least two selected from the group consisting of TiO₂, BaAl₂Si₂O₈, ZnAl₂O₄, and Zn₂SiO₄. Including at least two of these oxides can further decrease the TCC.

The one or more oxides of the ceramic crystalline components (C2) preferably include TiO₂ and at least one selected from the group consisting of BaAl₂Si₂O₈, ZnAl₂O₄, and Zn₂SiO₄. This is because BaAl₂Si₂O₈, ZnAl₂O₄, and Zn₂SiO₄ characteristically show an increase in permittivity with increasing temperature, and TiO₂ characteristically shows a decrease in permittivity with increasing temperature.

Preferred percentages of Ba₂Ti₉O₂₀, BaTi(BO₃)₂, BaTi₄O₉, BaTi₅O₁₁, Ba₄Ti₁₃O₃₀, BaZn₂Ti₄O₁₁, Ba₄ZnTi₁₁O₂₇, BaAl₂Si₂O₈, ZnAl₂O₄, Zn₂SiO₄, and TiO₂ as the oxides of the ceramic crystalline components in the high-permittivity ceramic are as follows.
Ba₂Ti₉O₂₀: 0 wt % to 55 wt %
BaTi(BO₃)₂: 0 wt % to 40 wt %
BaTi₄O₉: 0 wt % to 35 wt %
BaTi₅O₁₁: 0 wt % to 30 wt %
Ba₄Ti₁₃O₃₀: 0 wt % to 30 wt %
BaZn₂Ti₄O₁₁: 0 wt % to 30 wt %
Ba₄ZnTi₁₁O₂₇: 0 wt % to 25 wt %
BaAl₂Si₂O₈: 0 wt % to 40 wt %
ZnAl₂O₄: 0 wt % to 30 wt %
Zn₂SiO₄: 0 wt % to 15 wt %
TiO₂: 0.1 wt % to 10 wt %

The matters described in the following are common to the first low-temperature fired ceramic and the second low-temperature fired ceramic.

The low-temperature fired ceramic of the present disclosure may further contain CuO and/or Cu. CuO and/or Cu contained in the low-temperature co-fired ceramic (LTCC) material can promote the precipitation of BaAl₂Si₂O₄, ZnAl₂O₄, and Zn₂SiO₄ crystals from the RO—ZnO—Al₂O₃—B₂O₃—SiO₂ glass material during firing, reducing the amount of RO, ZnO, and Al₂O₃ in the glass material.

The sum of the percentage of CuO and the percentage of Cu in the low-temperature fired ceramic is preferably 1 wt % or less. The percentage of CuO and the percentage of Cu in the low-temperature fired ceramic can be determined by X-ray fluorescence. When firing of the low-temperature fired ceramic of the present disclosure is performed in an air atmosphere, copper exists in the form of CuO in the low-temperature fired ceramic. When firing is performed in a reducing atmosphere, copper exists in the form of Cu.

The percentages of the fired glass component and the oxides of the ceramic crystalline components in the low-temperature fired ceramic are not limited. For example, the percentage of the fired glass component in the low-temperature fired ceramic can be 10 wt % to 55 wt %, and the total percentage of the oxides of the ceramic crystalline components can be 45 wt % to 90 wt %. Particularly in the low-permittivity ceramic, preferably, the percentage of the fired glass component is 10 wt % to 30 wt %, and the total percentage of the oxides of the ceramic crystalline components is 70 wt % to 90 wt %. In the high-permittivity ceramic, preferably, the percentage of the fired glass component is 15 wt % to 55 wt %, and the total percentage of the oxides of the ceramic crystalline components is 45 wt % to 85 wt %.

The dielectric loss of the low-temperature fired ceramic is preferably 0.001 or less. In other words, the Q-factor, which is the reciprocal of the dielectric loss, is preferably 1000 or more.

The relative permittivity and the dielectric loss of the low-temperature fired ceramic herein are measured as the relative permittivity and the dielectric loss at 3 GHz by the perturbation method.

### First Electronic Component

The first electronic component of the present disclosure includes a low-temperature fired ceramic of the present disclosure. The low-temperature fired ceramic may be the low-permittivity ceramic or the high-permittivity ceramic.

Examples of the first electronic component of the present disclosure include a laminate including multiple low-temperature fired ceramic layers containing the low-temperature fired ceramic of the present disclosure, and a multilayer ceramic electronic component including a multilayer ceramic substrate including the laminate and a chip component mounted on the ceramic substrate.

The first electronic component of the present disclosure includes low-temperature fired ceramic layers containing the low-temperature fired ceramic of the present disclosure and thus has a small dielectric loss.

The laminate including multiple low-temperature fired ceramic layers containing the low-temperature fired ceramic of the present disclosure can be used as a ceramic multilayer substrate for communication or a multilayer dielectric filter, for example.

The first electronic component of the present disclosure has a small dielectric loss and a high Q-factor and thus is suitable as an electronic component that is used particularly in the millimeter wave band.

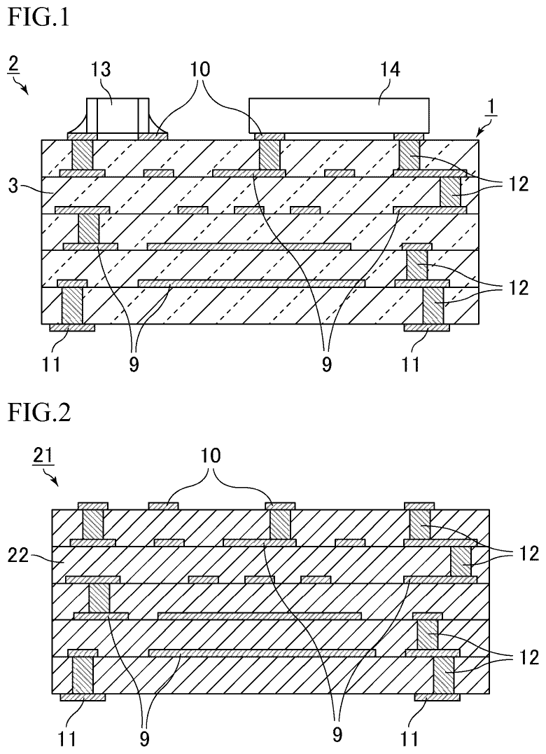

FIG. 1 is a schematic cross-sectional view of an example of a multilayer ceramic electronic component as the first electronic component of the present disclosure. As shown in FIG. 1, an electronic component 2 includes a laminate 1 including multiple low-temperature fired ceramic layers 3 (five layers in FIG. 1), and chip components 13 and 14 mounted on the laminate 1. The laminate 1 is also a multilayer ceramic substrate.

The low-temperature fired ceramic layers 3 are fired bodies containing the low-temperature fired ceramic of the present disclosure. Thus, the laminate 1 including the multiple low-temperature fired ceramic layers 3, and the electronic component 2 including a multilayer ceramic substrate including the laminate 1 and the chip components 13 and 14 mounted on the multilayer ceramic substrate (the laminate 1) are both the electronic components of the present disclosure. The multiple low-temperature fired ceramic layers 3 may each have the same composition or a different composition, but preferably the same.

The laminate 1 may further include conductive layers. For example, the conductive layers may define passive elements such as capacitors and inductors, or may define connection wiring for electric connection between elements. Such conductive layers include conductive layers 9, 10, and 11, and via hole conductive layers 12 shown in FIG. 1.

Preferably, the conductive layers 9, 10, and 11, and the via hole conductive layers 12 each contain Ag or Cu as a main component. Use of such a low-resistance metal prevents the occurrence of signal propagation delay associated with an increase in frequency of electric signals. Since the low-temperature fired ceramic layers 3 are fired bodies obtained by firing a low-temperature co-fired ceramic (LTCC) material, the low-temperature fired ceramic layers 3 can be formed by co-firing with Ag and Cu.

The first electronic component of the present disclosure preferably includes Cu wiring. Preferably, the electronic component includes Cu wiring formed by co-firing of a low-temperature co-fired ceramic (LTCC) material with Cu.

The conductive layers 9 are inside the laminate 1. Specifically, each conductive layer 9 is at an interface between the low-temperature fired ceramic layers 3.

The conductive layers 10 are on one of main surfaces of the laminate 1.

The conductive layers 11 are on the other main surface of the laminate 1.

Each via hole conductive layer 12 is disposed to penetrate the low-temperature fired ceramic layer 3 and plays a role in electrically connecting the conductive layers 9 at different levels to each other, electrically connecting the conductive layers 9 and 10 to each other, and electrically connecting the conductive layers 9 and 11 to each other.

The laminate 1 is produced as follows, for example.

### (A) Preparation of Glass Composition

B₂O₃, SiO₂, ZnO, Al₂O₃, and an alkaline earth metal oxide (RO) are mixed at a predetermined ratio to prepare a glass composition. The alkaline earth metal oxide is preferably BaO.

### (B) Preparation of Glass Powder

The glass composition is melted, and the resulting melt is quenched to produce cullet. The cullet is coarsely ground and is further ground in a ball mill or the like to prepare a glass powder having a predetermined particle size.

### (C) Preparation of Low-Temperature Co-Fired Ceramic (LTCC) Material

The glass powder is mixed with an oxide of a ceramic crystalline component to prepare a low-temperature co-fired ceramic (LTCC) material. When the low-permittivity ceramic is produced, the oxide of the ceramic crystalline component is at least one selected from the group consisting of SiO₂, BaAl₂Si₂O₈, ZnAl₂O₄, and Zn₂SiO₄. TiO₂ is preferably further used as the oxide of the ceramic crystalline component. When the high-permittivity ceramic is produced, the oxide of the ceramic crystalline component is at least one selected from the group consisting of Ba₂Ti₉O₂₀, BaTi(BO₃)₂, BaTi₄O₉, BaTi₅O₁₁, Ba₄Ti₁₃O₃₀, BaZn₂Ti₄O₁₁, and Ba₄ZnTin₁₁O₂₇. At least two selected from the group consisting of BaAl₂Si₂O₈, ZnAl₂O₄, Zn₂SiO₄, and TiO₂ are preferably further used as the oxides of the ceramic crystalline components.

The percentage of the glass powder in the low-temperature co-fired ceramic (LTCC) material is preferably 10 wt % to 55 wt %.

### (D) Production of Green Sheets

The low-temperature co-fired ceramic (LTCC) material is mixed with a binder, a plasticizer, etc., to prepare a ceramic slurry. Then, the ceramic slurry is applied to a base film (e.g., a polyethylene terephthalate (PET) film) and then dried to produce a green sheet.

### (E) Production of Multilayer Green Sheet

The green sheets are stacked to produce a multilayer green sheet (in an unfired state). FIG. 2 is a schematic cross-sectional view of a multilayer green sheet (in an unfired state) produced during the production process of the multilayer ceramic electronic component in FIG. 1. As shown in FIG. 2, a multilayer green sheet 21 includes a stack of multiple green sheets 22 (five sheets in FIG. 2). The green sheets 22 are converted into the low-temperature fired ceramic layers 3 after firing. The multilayer green sheet 21 may include conductive layers including the conductive layers 9, 10, and 11 and the via hole conductive layers 12. The conductive layers can be formed by a method such as screen printing or photolithography using a conductive paste containing Ag or Cu.

### (F) Firing of Multilayer Green Sheet

The multilayer green sheet 21 is fired. As a result, the laminate 1 shown in FIG. 1 is obtained.

The firing temperature of the multilayer green sheet 21 is not limited as long as it is a temperature at which the low-temperature co-fired ceramic (LTCC) material of the green sheets 22 can be sintered. For example, the firing temperature may be 1000° C. or lower.

The firing atmosphere of the multilayer green sheet 21 is not limited. Yet, when a material resistant to oxidation, such as Ag, is used to form the conductive layers 9, 10, and 11 and the via hole conductive layers 12, an air atmosphere is preferred; while when a material prone to oxidation, such as Cu, is used, a hypoxic atmosphere such as a nitrogen atmosphere is preferred. The firing atmosphere of the multilayer green sheet 21 may be a reducing atmosphere.

The multilayer green sheet 21 may be fired in a state of being sandwiched by restraint green sheets. The restraint green sheets contain, as a main component, an inorganic material (e.g., Al₂O₃) that is not substantially sintered at a sintering temperature of the low-temperature co-fired ceramic (LTCC) material of the green sheets 22. Thus, the restraint green sheets do not shrink at the time of firing of the multilayer green sheet 21, and act to reduce or prevent shrinkage in the main surface direction of the multilayer green sheet 21. This improves the dimensional accuracy of the resulting laminate 1 (particularly, the conductive layers 9, 10, and 11 and the via hole conductive layers 12).

The chip components 13 and 14 may be mounted on the laminate 1 while being electrically connected to the conductive layers 10. Thus, the electronic component 2 including the laminate 1 is configured.

Examples of the chip components 13 and 14 include LC filters, capacitors, and inductors.

The electronic component 2 may be mounted on a mounting board (e.g., motherboard) in an electrically connected manner via the conductive layers 11.

### Second Electronic Component

If a co-sintered body can be produced by stacking, compression-bonding, and co-sintering a sheet of a low-temperature fired ceramic with low permittivity and a sheet of a low-temperature fired ceramic with high permittivity, such a co-sintered body can be used as an LTCC substrate, with wiring or a coil being formed in the low-permittivity layer and a capacitor being formed in the high-permittivity layer. This will enable smaller electronic components. The prior art, however, has not disclosed such a co-fired body.

Co-sintering of materials with different permittivities may cause defects such as delamination, pores, or cracks due to reaction between the materials or difference in shrinkage behavior between the materials during firing. The prior art has not disclosed how to eliminate these defects.

The second electronic component of the present disclosure includes a low-permittivity ceramic layer and a high-permittivity ceramic layer. The low-permittivity ceramic layer contains a first low-temperature fired ceramic. The high-permittivity ceramic layer contains a second low-temperature fired ceramic.

The first low-temperature fired ceramic contains a fired glass component (A1) and one or more oxides of ceramic crystalline components (C1). The second low-temperature fired ceramic contains a fired glass component (A2) and one or more oxides of ceramic crystalline components (C2).

The fired glass component (A1) is represented by RO—ZnO—Al₂O₃—B₂O₃—SiO₂. RO is at least one selected from the group consisting of MgO, CaO, SrO, and BaO. The percentage of RO, the percentage of ZnO, and the percentage of Al₂O₃ in the fired glass component (A1) are each 0.1 mol % to 10 mol %. The sum of the percentage of RO, the percentage of ZnO, and the percentage of Al₂O₃ in the fired glass component (A1) is 15 mol % or less. The ratio of the percentage of SiO₂ to the percentage of B₂O₃(SiO₂/B₂O₃) in the fired glass component (A1) is less than 3.4.

The one or more oxides of the ceramic crystalline components (C1) include BaAl₂Si₂O₈ and at least two selected from the group consisting of SiO₂, ZnAl₂O₄, Zn₂SiO₄, and TiO₂. The second electronic component of the present disclosure includes a co-sintered body produced by stacking, compression-bonding, and co-sintering a sheet of a low-temperature fired ceramic with low permittivity and a sheet of a low-temperature fired ceramic with high permittivity. To reduce or prevent delamination, the one or more oxides of the ceramic crystalline components (C1) need to include BaAl₂Si₂O₈.

The fired glass component (A2) is the same as the fired glass component (A1), except that the fired glass component (A2) is not limited in the ratio of the percentage of SiO₂ to the percentage of B₂O₃.

The one or more oxides of the ceramic crystalline components (C2) include at least one barium titanate compound selected from the group consisting of Ba₂Ti₉O₂₀, BaTi(BO₃)₂, BaTi₄O₉, BaTi₅O₁₁, Ba₄Ti₁₃O₃, BaZn₂Ti₄O₁, and Ba₄ZnTin₁₁O₂₇. The sum of the percentage of Ba₂Ti₉O₂₀, the percentage of BaTi(BO₃)₂, the percentage of BaTi₄O₉, the percentage of BaTi₅O₁₁, the percentage of Ba₄Ti₁₃O₃₀, the percentage of BaZn₂Ti₄O₁₁, and the percentage of Ba₄ZnTi₁₁O₂₇ in the second low-temperature fired ceramic is preferably 40 wt % or more.

In the first low-temperature fired ceramic, the percentage of Al₂O₃ is more than 0 wt % and 5 wt % or less, and the percentage of BaAl₂Si₂O₈ is more than 0 wt % and 5 wt % or less.

The first low-temperature fired ceramic may be the same as the low-permittivity ceramic described above except that the one or more oxides of the ceramic crystalline components (C1) need to include BaAl₂Si₂O₈, the first low-temperature fired ceramic further contains Al₂O₃ in addition to Al₂O₃ contained in the fired glass component (A1), and the percentage of Al₂O₃ in the first low-temperature fired ceramic, excluding Al₂O₃ contained in the fired glass component (A1), is more than 0 wt % and 5 wt % or less. The second low-temperature fired ceramic may be the same as the high-permittivity ceramic described above.

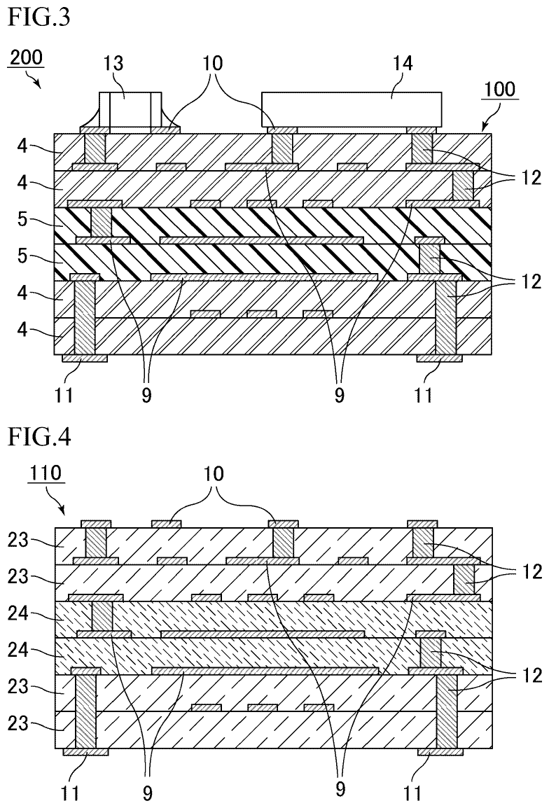

The second electronic component of the present disclosure is described below referring to FIG. 3 and FIG. 4. Only the portions different from those of the first electronic component are described.

FIG. 3 is a schematic cross-sectional view of an example of a multilayer ceramic electronic component as the second electronic component of the present disclosure.

As shown in FIG. 3, an electronic component 200 includes a laminate 100 including two low-permittivity ceramic layers 4, two high-permittivity ceramic layers 5, and additional two low-permittivity ceramic layers 4. The electronic component 200 also includes chip components 13 and 14 mounted on the laminate 100. The laminate 100 is also a multilayer ceramic substrate.

The low-permittivity ceramic layers 4 are fired bodies containing the low-permittivity ceramic described above. The high-permittivity ceramic layers 5 are fired bodies containing the high-permittivity ceramic described above. The multiple low-permittivity ceramic layers 4 may each have the same composition or a different composition, but preferably the same. The multiple high-permittivity ceramic layers 5 may each have the same composition or a different composition, but preferably the same. The laminate 100 may further include conductive layers.

The second electronic component of the present disclosure preferably includes Cu wiring. Preferably, the electronic component includes Cu wiring formed by co-firing of a low-temperature co-fired ceramic (LTCC) material with Cu.

The laminate 100 is produced as follows, for example.

(A) Preparation of Glass Composition, (B) Preparation of Glass Powder, (C) Preparation of Low-Temperature Co-fired Ceramic (LTCC) Material, and (D) Production of Green Sheets can be performed in the same manner as in the production of the laminate 1 of the first electronic component, except that two types of materials, one for the low-permittivity ceramic and the other for the high-permittivity ceramic, are prepared.

### (E) Production of Multilayer Green Sheet

FIG. 4 is a schematic cross-sectional view of a multilayer green sheet (in an unfired state) produced during the production process of the multilayer ceramic electronic component in FIG. 3. As shown in FIG. 4, a multilayer green sheet 110 includes two low-permittivity ceramic layer green sheets 23, two high-permittivity ceramic layer green sheets 24, and additional two low-permittivity ceramic layer green sheets 23. The low-permittivity ceramic layer green sheets 23 are converted into the low-permittivity ceramic layers 4 after firing. The high-permittivity ceramic layer green sheets 24 are converted into the high-permittivity ceramic layers 5 after firing. The low-permittivity ceramic layer green sheets 23 and the high-permittivity ceramic layer green sheets 24 may include conductive layers, including the conductive layers 9, 10, and 11 and the via hole conductive layers 12.

### (F) Firing of Multilayer Green Sheet

The multilayer green sheet 110 is fired. As a result, the laminate 100 shown in FIG. 3 is obtained.

The second electronic component of the present disclosure includes the low-permittivity ceramic and high-permittivity ceramic that are the low-temperature fired ceramics of the present disclosure. The second electronic component of the present disclosure thus has less reaction between the materials and less difference in shrinkage behavior between the materials during firing, and is less likely to have defects such as delamination, pores, or cracks.

### EXAMPLES

The following describes examples that more specifically disclose the low-temperature fired ceramics and the electronic components of the present disclosure. The present disclosure is not limited to these examples.

### Production of Low-Permittivity Ceramics 1

### (A) Preparation of Glass

Glass powders G1 to G7 (all in the powder form) were produced by the following method. First, powdered glass raw materials were mixed to obtain a glass composition. The glass composition was placed in a crucible made of Pt and melted in an air atmosphere at 1600° C. for 30 minutes or longer. Subsequently, the resulting melt was quenched to obtain cullet. Carbonate (BaCO₃) was used as a raw material of an alkaline earth metal oxide (BaO). Although carbonate (BaCO₃) is converted into an alkaline earth metal oxide (BaO) by firing, Table 1 shows the blending amounts in terms of BaO.

The cullet was coarsely ground. Then, the ground cullet was placed in a container together with ethanol and PSZ balls (diameter: 5 mm) and mixed in a ball mill. When mixing in the ball mill, the grinding time was adjusted, whereby a glass powder having a median particle size of 1.0 m was obtained. Here, the term “median particle size” refers to the median particle size D50 determined by the laser diffraction scattering method.

### (B) Production of Green Sheets

Next, glass powders G1 to G7 and oxides of ceramic crystalline components C1 to C7 (median particle size: 1.0 m) in the combinations shown in Table 1 were placed in ethanol and mixed in a ball mill. Each of the resulting mixtures was further mixed with a binder solution prepared by dissolving polyvinyl butyral in ethanol and a dioctyl phthalate (DOP) solution as a plasticizer to give a slurry. The slurry was applied to a PET film using a doctor blade and dried at 40° C. to obtain a 50-micron-thick green sheet.

### (C) Production of Evaluation Samples and Evaluation

### Relative Permittivity and Q-Factor

To prepare samples for evaluation of the relative permittivity and Q-factor, the green sheet was cut into 50-mm square pieces, and 20 of these pieces were stacked, placed in a mold, and compression-bonded using a pressing machine. The compression-bonded body was fired in an air atmosphere at a temperature of 900° C. or higher and 950° C. or lower for 60 minutes, whereby a low-temperature fired ceramic was obtained. The relative permittivity and Q-factor (reciprocal of dielectric loss) of the obtained low-temperature fired ceramic were measured by the perturbation method at 25° C. and 3 GHz. The measurement conditions were as follows.

### Measurement Device and Measurement Conditions:

Network analyzer: 8757D available from Keysight Technologies

Signal generator: Keysight 83751 synthesized sweeper available from Keysight Technologies

Resonator: scratch-built jig (resonant frequency: 3 GHz)

Prior to the measurement, the network analyzer and the signal generator were connected to each other to measure cable loss. The resonator was calibrated using a standard substrate (made of quartz; relative permittivity: 3.73; Q-factor: 9091 at 3 GHz; thickness: 0.636 mm).

### Temperature Coefficient of Capacitance (TCC)

To prepare samples for evaluation of TCC, the green sheet was cut into 10-mm square pieces, and 20 of these pieces were stacked, placed in a mold, and compression-bonded using a pressing machine. The entire upper and lower main surfaces of this compression-bonded body were printed with pure Cu paste as opposing electrodes of the capacitor. The sample was dried and then fired in a reducing atmosphere at a temperature of 900° C. or higher and 950° C. or lower for 60 minutes. The fired sample was placed in a thermostat chamber. The relative permittivity of the sample was measured using an LCR meter (Agilent, model: E4980A) in the range of −40° C. to 125° C. The temperature coefficient of capacitance (TCC) was determined, and the temperature dependence of relative permittivity was evaluated.

### Composition of Low-Temperature Fired Ceramic

To further analyze the composition of the fired body, the fired body was measured by powder XRD at a low scanning rate of (0.2 deg/min), and the percentage of the fired glass component of the fired body and the composition of the fired glass component were determined by Rietveld analysis. The composition was determined based on the assumption that the total amount of oxides of the elements would be the same before and after firing.

The compositions of the oxides of the ceramic crystalline components of the fired body were also determined.

The percentage of CuO and the percentage of Cu in the fired body were determined by X-ray fluorescence.

Table 1 shows the results.

TABLE 1

| | Glass | Ceramic | | | | | | | |
|---|---|---|---|---|---|---|---|---|---|
| Sample | powder | powder | Fired low-temperature fired ceramic (wt %) | | | | | | |
| No. | No. | No. | SiO₂ | BaAl₂Si₂O₈ | ZnAl₂O₄ | Zn₂SiO₄ | TiO₂ | CuO/Cu | Glass |
| L1 | G1 | C1 | 18.7 | 17.3 | 10.5 | 0.0 | 3.5 | 0.0 | 50.0 |
| L2 | G2 | C2 | 32.1 | 10.7 | 18.6 | 2.3 | 2.0 | 2.0 | 32.3 |
| L3 | G3 | C3 | 10.5 | 10.4 | 15.5 | 1.5 | 10.0 | 0.0 | 52.1 |
| L4 | G4 | C4 | 42.6 | 19.3 | 11.3 | 0.8 | 0.0 | 0.0 | 26.0 |
| L5 | G5 | C5 | 28.5 | 22.5 | 2.1 | 18.3 | 0.5 | 1.0 | 27.1 |
| L6 | G6 | C6 | 38.7 | 16.5 | 20.7 | 0.4 | 3.0 | 0.5 | 20.2 |
| L7 | G7 | C7 | 33.7 | 14.5 | 21.5 | 0.3 | 12.0 | 0.2 | 17.8 |

| | | | | | | | Electrical characteristics | | |
|---|---|---|---|---|---|---|---|---|---|
| | | | | | | | (measured at 3 GHz) | | |
| Sample | Fired glass component (mol %) | | | | | | Relative | Q- | TCC |
| No. | BaO | ZnO | Al₂O₃ | B₂O₃ | SiO₂ | SiO₂/B₂O₃ | permittivity | factor | (ppm ° C.⁻¹) |
| L1 | 1.9 | 2.1 | 8.7 | 33.7 | 53.6 | 1.6 | 5.8 | 1470 | 5 |
| L2 | 9.3 | 2.3 | 3.8 | 30.8 | 53.8 | 1.7 | 4.3 | 880 | 15 |
| L3 | 13.2 | 4.2 | 2.5 | 28.1 | 52.0 | 1.9 | 6.2 | 530 | −55 |
| L4 | 2.7 | 15.3 | 16.3 | 23.9 | 41.8 | 1.7 | 4.1 | 220 | 75 |
| L5 | 2.5 | 2.8 | 1.8 | 30.3 | 62.6 | 2.1 | 4.2 | 2230 | 60 |
| L6 | 0.4 | 4.2 | 2.4 | 33.4 | 59.6 | 1.8 | 4.8 | 2430 | 13 |
| L7 | 1.8 | 2.1 | 4.7 | 36.6 | 54.8 | 1.5 | 6.4 | 1960 | −120 |

The fired low-temperature fired ceramics of sample Nos. L1 and L5 to L7 each corresponded to a low-temperature fired ceramic of the present disclosure, because the percentage of BaO (percentage of RO), the percentage of ZnO, and the percentage of Al₂O₃ in the fired glass component were each 0.1 mol % to 10 mol %, the sum of the percentage of BaO (percentage of RO), the percentage of ZnO, and the percentage of Al₂O₃ in the fired glass component was 15 mol % or less, and the ratio of the percentage of SiO₂ to the percentage of B₂O₃(SiO₂/B₂O₃) was less than 3.4, and the oxides of the ceramic crystalline components (C1) included at least one selected from the group consisting of SiO₂, BaAl₂Si₂O₈, ZnAl₂O₄, and Zn₂SiO₄.

Each of these samples had a high Q-factor, indicating a low-temperature fired ceramic with a small dielectric loss. Each of the samples also had a low relative permittivity.

Sample Nos. L1, L5, and L6 each had a TCC in the range of −60 ppm ° C.⁻¹ to 60 ppm ° C.⁻¹, indicating a low temperature dependence of relative permittivity. Sample No. L7 had a TCC less than 60 ppm ° C.⁻¹, presumably because of its high TiO₂ content.

### Production of High-Permittivity Ceramics 1

### Preparation of Glass

Glass powders G1 to G10 (all in the powder form) were produced as in “(A) Preparation of Glass” in Production of Low-Permittivity Ceramics 1. Of glass powders G1 to G10, glass powders G1 to G7 were the same as glass powders G1 to G7 prepared in the production of the low-permittivity ceramic.

### Production of Green Sheets

Green sheets were obtained as in “(B) Production of Green Sheets” in Production of Low-Permittivity Ceramics 1, except that glass powders G1 to G10 and oxides of ceramic crystalline components C8 to C17 (median particle size: 1.0 in) were used in the combinations shown in Table 2.

### Production of Evaluation Samples and Evaluation

Low-temperature fired ceramics were obtained as in “(C) Production of Evaluation Samples and Evaluation” in Production of Low-Permittivity Ceramics 1. The relative permittivity, Q-factor, TCC and composition of the obtained low-temperature fired ceramics were determined.

Table 2 shows the results.

TABLE 2

| | Glass | Ceramic | | | | | | | | |
|---|---|---|---|---|---|---|---|---|---|---|
| Sample | powder | powder | Fired low-temperature fired ceramic (wt %) | | | | | | | |
| No. | No. | No. | Ba₂Ti₉O₂₀ | BaTi(BO₃)₂ | BaAl₂Si₂O₈ | ZnAl₂O₄ | Zn₂SiO₄ | TiO₂ | CuO/Cu | Glass |
| H1 | G1 | C8 | 36.0 | 5.1 | 17.8 | 13.5 | 1.3 | 1.2 | 0.0 | 25.1 |
| H2 | G2 | C9 | 43.0 | 3.2 | 16.4 | 1.1 | 8.5 | 3.5 | 0.0 | 24.3 |
| H3 | G3 | C10 | 38.5 | 11.2 | 16.4 | 14.2 | 0.5 | 5.0 | 0.0 | 14.2 |
| H4 | G4 | C11 | 42.7 | 17.1 | 13.8 | 2.5 | 0.1 | 1.5 | 0.5 | 21.8 |
| H5 | G5 | C12 | 41.5 | 13.5 | 14.2 | 8.5 | 0.2 | 7.0 | 0.5 | 14.6 |
| H6 | G6 | C13 | 40.0 | 12.0 | 15.2 | 9.0 | 0.0 | 1.5 | 1.0 | 21.3 |
| H7 | G7 | C14 | 50.1 | 6.3 | 10.9 | 7.1 | 0.0 | 1.5 | 0.5 | 23.6 |
| H8 | G8 | C15 | 18.8 | 22.1 | 24.7 | 11.3 | 0.3 | 2.0 | 0.5 | 20.3 |
| H9 | G9 | C16 | 35.9 | 3.5 | 29.7 | 13.2 | 0.1 | 2.0 | 0.0 | 15.6 |
| H10 | G10 | C17 | 15.0 | 11.5 | 32.1 | 18.9 | 0.1 | 0.0 | 0.0 | 22.4 |

| | | | | | | Electrical characteristics | | |
|---|---|---|---|---|---|---|---|---|
| | | | | | | (measured at 3 GHz) | | |
| Sample | Fired glass component (mol %) | | | | | Relative | Q- | TCC |
| No. | BaO | ZnO | Al₂O₃ | B₂O₃ | SiO₂ | permittivity | factor | (ppm ° C.⁻¹) |
| H1 | 2.3 | 2.1 | 9.2 | 33.7 | 52.7 | 16.0 | 1520 | 12 |
| H2 | 9.3 | 2.3 | 4.1 | 30.8 | 53.5 | 17.5 | 820 | −23 |
| H3 | 14.3 | 4.2 | 1.9 | 28.1 | 51.5 | 20.2 | 640 | −25 |
| H4 | 3.1 | 15.3 | 15.7 | 23.9 | 42.0 | 26.2 | 310 | 6 |
| H5 | 2.5 | 2.8 | 2.1 | 30.3 | 62.3 | 23.6 | 2240 | −30 |
| H6 | 0.4 | 4.2 | 2.2 | 33.4 | 59.8 | 22.3 | 2400 | 5 |
| H7 | 1.8 | 2.1 | 5.6 | 36.6 | 53.9 | 29.3 | 1970 | 8 |
| H8 | 1.8 | 2.1 | 1.2 | 19.8 | 75.1 | 16.4 | 2950 | −5 |
| H9 | 5.3 | 5.2 | 4.1 | 31.0 | 54.4 | 14.2 | 1240 | −8 |
| H10 | 4.9 | 2.6 | 1.3 | 31.6 | 59.6 | 13.2 | 1160 | 55 |

The fired low-temperature fired ceramics of sample Nos. H1 and H5 to H10 each corresponded to a low-temperature fired ceramic of the present disclosure, because the percentage of BaO (percentage of RO), the percentage of ZnO, and the percentage of Al₂O₃ in the fired glass component were each 0.1 mol % to 10 mol %, the sum of the percentage of BaO (percentage of RO), the percentage of ZnO, and the percentage of Al₂O₃ in the fired glass component was 15 mol % or less, and the oxides of the ceramic crystalline components (C2) included at least one selected from the group consisting of Ba₂Ti₉O₂₀, BaTi(BO₃)₂, BaTi₄O₉, BaTi₅O₁₁, Ba₄Ti₁₃O₃₀, BaZn₂Ti₄O₁₁, and Ba₄ZnTi₁₁O₇.

Each of these samples had a high Q-factor, indicating a low-temperature fired ceramic with a small dielectric loss. Each of these samples also had a TCC in the range of −60 ppm ° C.⁻¹ to 60 ppm ° C.⁻¹ indicating a low temperature dependence of relative permittivity. Each of the samples also had a high relative permittivity.

### Production of Electronic Components Including Low-Permittivity Ceramic Layers and High-Permittivity Ceramic Layers 1

### Preparation of Glass

Glass powders G1, G11, and G12 (all in the powder form) were produced as in “(A) Preparation of Glass” in Production of Low-Permittivity Ceramics 1. Glass powder G1 was the same as glass powder G1 prepared in Production of Low-Permittivity Ceramics 1.

### Production of Green Sheets

Low-permittivity green sheets were obtained as in “(B) Production of Green Sheets” in Production of Low-Permittivity Ceramics 1, except that glass powders G1, G11, and G12 and oxides of ceramic crystalline components C1, C3, and C18 (median particle size: 1.0 m) were used in the combinations shown in Table 3. The oxides of the ceramic crystalline components C1 and C3 were the same as C1 and C3 used in Production of Low-Permittivity Ceramics 1.

Separately, high-permittivity green sheets were obtained as in “(B) Production of Green Sheets” in Production of Low-Permittivity Ceramics 1, except that glass powders G1, G11, and G12 and oxides of ceramic crystalline components C8, C19, and C20 (median particle size: 1.0 m) were used in the combinations shown in Table 4. The oxides of the ceramic crystalline components C8 were the same as C8 used in Production of High-Permittivity Ceramics 1.

### Production of Evaluation Samples and Evaluation

The samples for evaluating sinterability were prepared as follows. The low-permittivity green sheets and high-permittivity green sheets produced above were cut into 50-mm square pieces. In each of the combinations shown in Table 5, eight pieces of the low-permittivity green sheet, four pieces of the high-permittivity green sheet, and eight pieces of the low-permittivity green sheet were stacked in sequence, placed in a mold, and compression-bonded using a pressing machine. The compression-bonded body was fired in a reducing atmosphere at a temperature of 900° C. or higher and 950° C. or lower for 60 minutes, whereby a fired body was obtained.

The fired body was embedded in resin, followed by curing. The cross section was polished and examined with a scanning electron microscope (SEM) for the presence or absence of defects such as delamination, pores, or cracks at the boundaries between the ceramic layers with different relative permittivities.

The composition of the glass in the fired body was determined as follows: a glass area of an exfoliated sample was identified using a scanning transmission electron microscope (STEM) and electron diffraction, and the glass area was analyzed by wavelength dispersive X-ray analysis (WDS) to determine the composition of the glass. The crystal species and crystal contents in the ceramic layers with low permittivity in the fired body were determined by performing XRD on the surface of the fired body sample. The crystal species and crystal contents in the ceramic layers with high permittivity were determined by polishing away the low permittivity portion from the surface of the fired body sample to expose the layer with high permittivity, and performing XRD on the exposed surface.

Table 3 shows the compositions of the ceramic layers with low relative permittivity. Table 4 shows the compositions of the ceramic layers with high relative permittivity. Table 5 shows the presence or absence of defects at the boundaries between the ceramic layers with different relative permittivities.

TABLE 3

| | Glass | Ceramic | | | | | | | | | | | | |
|---|---|---|---|---|---|---|---|---|---|---|---|---|---|---|
| Sample | powder | powder | Fired low-temperature fired ceramic (wt %) | | | | | | | Fired glass component (mol %) | | | | |
| No. | No. | No. | SiO₂ | BaAl₂Si₂O₈ | ZnAl₂O₄ | Zn₂SiO₄ | TiO₂ | CuO/Cu | Glass | BaO | ZnO | Al₂O₃ | B₂O₃ | SiO₂ |
| L1 | G1 | C1 | 18.7 | 17.3 | 10.5 | 0.0 | 3.5 | 0.0 | 50.0 | 1.9 | 2.1 | 8.7 | 33.7 | 53.6 |
| L8 | G11 | C18 | 15.8 | 16.2 | 14.8 | 4.7 | 2.4 | 0.0 | 46.1 | 8.5 | 0.0 | 0.0 | 35.4 | 56.1 |
| L9 | G12 | C3 | 10.5 | 10.4 | 15.5 | 1.5 | 10.0 | 0.0 | 52.1 | 0.0 | 4.6 | 7.5 | 33.8 | 54.1 |

TABLE 4

| | Glass | Ceramic | | | | | | | | | | | | | |
|---|---|---|---|---|---|---|---|---|---|---|---|---|---|---|---|
| Sam- | pow- | pow- | | | | | | | | | | | | | |
| ple | der | der | Fired low-temperature fired ceramic (wt %) | | | | | | | | Fired glass component (mol %) | | | | |
| No. | No. | No. | Ba₂Ti₉O₂₀ | BaTi(BO₃)₂ | BaAl₂Si₂O₈ | ZnAl₂O₄ | Zn₂SiO₄ | TiO₂ | CuO/Cu | Glass | BaO | ZnO | Al₂O₃ | B₂O₃ | SiO₂ |
| H1 | G1 | C8 | 36.0 | 5.1 | 17.8 | 13.5 | 1.3 | 1.2 | 0.0 | 25.1 | 2.3 | 2.1 | 9.2 | 33.7 | 52.7 |
| H11 | G11 | C19 | 34.2 | 7.5 | 12.4 | 15.6 | 0.5 | 1.5 | 0.0 | 28.3 | 7.9 | 0.0 | 0.0 | 35.1 | 57.0 |
| H12 | G12 | C20 | 37.4 | 8.3 | 13.6 | 14.5 | 0.4 | 1.4 | 0.0 | 24.4 | 0.0 | 6.8 | 5.3 | 35.2 | 52.7 |

TABLE 5

| | High- | Low- | |
|---|---|---|---|
| | permittivity | permittivity | |
| Sample No. | layer | layer | Boundary state |
| E1 | H1 | L1 | No defects |
| E2 | H1 | L8 | Delamination |
| E3 | H11 | L9 | Pores, cracks |
| E4 | H12 | L1 | Delamination, pores |
| E5 | H12 | L9 | Pores, cracks |

The electronic component of sample No. E1 corresponded to an electronic component of the present disclosure because both the low-permittivity ceramic layers and the high-permittivity ceramic layers contained low-temperature fired ceramics of the present disclosure.

In the electronic component of sample No. E1, no defects were found at the boundaries between the low-permittivity ceramic layers and the high-permittivity ceramic layers. In the electronic components of sample Nos. E2 to E5, at least either the low-permittivity ceramic layers or the high-permittivity ceramic layers contained a low-temperature fired ceramic outside the present disclosure. In these electronic components, defects such as delamination, pores, or cracks were observed at the boundaries between the low-permittivity ceramic layers and the high-permittivity ceramic layers.

### Production of Low-Permittivity Ceramics 2

### Preparation of Glass

Glass powders were produced as in “(A) Preparation of Glass” in Production of Low-Permittivity Ceramics 1 such that the fired glass components had the values shown in Table 6.

### Production of Green Sheets

Next, green sheets were obtained as in “(B) Production of Green Sheets” in Production of Low-Permittivity Ceramics 1, except that glass powders produced above and oxides of ceramic crystalline components (median particle size: 1.0 μm) were used such that the fired low-temperature fired ceramics had compositions according to the values shown in Table 6.

### Production of Evaluation Samples and Evaluation

Low-temperature fired ceramics were obtained as in “(C) Production of Evaluation Samples and Evaluation” in Production of Low-Permittivity Ceramics 1. The relative permittivity, Q-factor, TCC and composition of the obtained low-temperature fired ceramics were determined.

Table 6 shows the results.

TABLE 6

| | Fired low-temperature fired ceramic (wt %) | | | | | | | | |
|---|---|---|---|---|---|---|---|---|---|
| Sample | SiO₂ | SiO₂ | | | | | | | |
| No. | (quartz) | (amorphous) | Al₂O₃ | BaAl₂Si₂O₈ | ZnAl₂O₄ | Zn₂SiO₄ | TiO₂ | CuO/Cu | Glass |
| L10 | 31.3 | 0.0 | 0.0 | 5.1 | 20.2 | 0.5 | 0.0 | 0.0 | 42.9 |
| L11 | 28.5 | 0.0 | 0.0 | 9.8 | 19.4 | 1.0 | 0.0 | 0.0 | 41.3 |
| L12 | 22.7 | 0.0 | 0.0 | 2.3 | 25.9 | 2.5 | 0.0 | 0.0 | 46.6 |
| L13 | 16.1 | 0.0 | 0.0 | 0.5 | 32.1 | 5.2 | 2.0 | 0.0 | 44.1 |
| L14 | 18.5 | 11.5 | 0.0 | 0.3 | 21.7 | 0.0 | 0.0 | 0.0 | 48.0 |
| L15 | 15.1 | 0.0 | 0.0 | 10.5 | 18.6 | 0.0 | 5.0 | 1.0 | 49.8 |
| L16 | 12.3 | 21.3 | 0.0 | 0.0 | 5.0 | 12.7 | 0.0 | 0.0 | 48.7 |
| L17 | 25.2 | 0.0 | 5.1 | 0.3 | 16.5 | 1.4 | 0.0 | 0.0 | 51.5 |
| L18 | 27.2 | 0.0 | 3.2 | 0.3 | 18.3 | 0.00 | 0.0 | 0.0 | 51.0 |

| | | | | | | | Electrical characteristics | | |
|---|---|---|---|---|---|---|---|---|---|
| | | | | | | | (measured at 3 GHz) | | |
| | Fired glass component (mol %) | | | | | | | | TCC |
| Sample | | | | | | SiO₂/ | Relative | Q- | (ppm ° |
| No. | BaO | ZnO | Al₂O₃ | B₂O₃ | SiO₂ | B₂O₃ | permittivity | factor | C.⁻¹) |
| L10 | 0.4 | 3.4 | 0.8 | 27.2 | 68.2 | 2.5 | 4.2 | 1470 | 22 |
| L11 | 0.3 | 2.8 | 1.2 | 38.2 | 57.5 | 1.5 | 4.1 | 1550 | 55 |
| L12 | 0.8 | 0.6 | 0.5 | 32.5 | 65.6 | 2.0 | 4.0 | 1720 | 17 |
| L13 | 2.1 | 1.2 | 1.5 | 21.7 | 73.5 | 3.4 | 3.5 | 230 | −3 |
| L14 | 1.7 | 0.8 | 1.4 | 30.6 | 65.5 | 2.1 | 3.9 | 1870 | 8 |
| L15 | 0.3 | 0.7 | 0.8 | 30.5 | 67.7 | 2.2 | 4.5 | 1580 | −4 |
| L16 | 1.3 | 2.8 | 2.4 | 23.1 | 70.4 | 3.0 | 4.0 | 1930 | 15 |
| L17 | 0.2 | 2.6 | 2.5 | 34.2 | 60.5 | 1.8 | 4.2 | 1450 | 12 |
| L18 | 1.2 | 2.3 | 2.1 | 33.8 | 60.6 | 1.8 | 4.2 | 1580 | 10 |

The fired low-temperature fired ceramics of sample Nos. L10 to L12 and L14 to L18 each corresponded to a low-temperature fired ceramic of the present disclosure, because the percentage of BaO (percentage of RO), the percentage of ZnO, and the percentage of Al₂O₃ in the fired glass component were each 0.1 mol % to 10 mol %, the sum of the percentage of BaO (percentage of RO), the percentage of ZnO, and the percentage of Al₂O₃ in the fired glass component was 15 mol % or less, the ratio of the percentage of SiO₂ to the percentage of B₂O₃(SiO₂/B₂O₃) was less than 3.4, and the oxides of the ceramic crystalline components (C1) included at least one selected from the group consisting of SiO₂, BaAl₂Si₂O₈, ZnAl₂O₄, and Zn₂SiO₄.

Sample No. L10 contained 5.1 wt % of BaAl₂Si₂O₈. Sample No. L11 contained 9.8 wt % of BaAl₂Si₂O₈. Neither of the samples contained TiO₂. Therefore, sample No. L10 and sample No. L11 had higher TCCs than sample Nos. L12 to L18.

Sample No. L13 had a SiO₂/B₂O₃ ratio of 3.4 and had a low Q-factor due to sintering failure.

### Production of High-Permittivity Ceramics 2

### Preparation of Glass

Glass powders were produced as in “(A) Preparation of Glass” in Production of Low-Permittivity Ceramics 1 such that the fired glass components had the values shown in Table 7.

### Production of Green Sheets

Next, green sheets were obtained as in “(B) Production of Green Sheets” in Production of Low-Permittivity Ceramics 1, except that glass powders produced above and oxides of ceramic crystalline components (median particle size: 1.0 in) were used such that the fired low-temperature fired ceramics had compositions according to the values shown in Table 7.

### Production of Evaluation Samples and Evaluation

Low-temperature fired ceramics were obtained as in “(C) Production of Evaluation Samples and Evaluation” in Production of Low-Permittivity Ceramics 1. The relative permittivity, Q-factor, TCC and composition of the obtained low-temperature fired ceramics were determined.

Table 7 shows the results.

TABLE 7

| Sample | Fired low-temperature fired ceramic (wt %) | | | | | | | | | |
|---|---|---|---|---|---|---|---|---|---|---|
| No. | Ba [symbol] Ti [symbol] O [symbol] | BaT [symbol] (BO [symbol] ) [symbol] | BaAl₂Si₂O [symbol] | ZnAl₂O₄ | Zn₂SiO₄ | TiO₂ | BaTi [symbol] O [symbol] | BaTi [symbol] O [symbol] | Ba [symbol] Ti [symbol] O [symbol] | BaZn [symbol] Ti [symbol] O [symbol] |
| H13 | 6.2 | 3.4 | 23.7 | 10.5 | 0.0 | 3.1 | 14.2 | 0.0 | 15.2 | 2.3 |
| H14 | 0.0 | 9.2 | 27.3 | 8.2 | 0.0 | 0.0 | 2.3 | 0.0 | 19.5 | 0.0 |
| H15 | 0.0 | 5.7 | 15.3 | 15.3 | 0.0 | 1.5 | 1. [symbol] | 0.0 | 11.2 | 10.7 |
| H16 | 8.3 | 0.0 | 20.2 | 12.4 | 0.0 | 2.7 | 12.8 | 0.0 | [symbol] .6 | 10.3 |
| H17 | 12.4 | 2.4 | 18.3 | 9.7 | 0.0 | 1.2 | 0.0 | 13.9 | 0.0 | 5.8 |
| H18 | 20.8 | 3.7 | 12.8 | 12.6 | 0.0 | 3.6 | 2.1 | 7.3 | 0.0 | 3.6 |
| H19 | 0.0 | 12.5 | 18.6 | 0.0 | 4.7 | 1.3 | 0.0 | 10. [symbol] | 0.0 | 13.5 |
| H20 | 0.0 | 10.6 | 20.5 | 0.0 | 1.5 | 1.2 | 0.0 | 12.5 | 0.0 | 20.4 |
| H21 | 0.0 | 9.5 | 17.9 | 0.0 | 0.5 | 1.5 | 0.0 | 22.4 | 5.2 | 5.3 |
| H22 | 0.0 | 8.3 | 19.1 | 0.0 | 2.5 | 1.6 | 3.2 | 18.3 | 0.0 | 10.1 |
| H23 | 0.0 | 5.3 | 19.7 | 1.2 | 2.8 | 2.1 | 10.2 | 10.5 | 0.0 | 10.3 |
| H24 | 0.0 | 7.2 | 35.9 | 0.0 | 1.3 | 2.3 | 15.4 | 3.5 | 0.0 | 2.4 |
| H25 | 0.0 | 9.6 | 27.5 | 12.5 | 0.0 | 0.0 | 0.0 | 17.3 | 0.0 | 0.0 |
| H26 | 0.0 | 3.5 | 31.6 | 9.8 | 0.0 | 2.0 | 0.0 | 5.7 | 18.3 | 12.3 |
| H27 | 0.0 | 13.2 | 22.7 | 11.6 | 0.0 | 1.8 | 0.0 | 20.7 | 0.0 | 0.0 |
| H28 | 0.0 | 0.0 | 36.1 | 4.8 | 0.0 | 2.2 | 17.3 | 0.0 | 5.2 | 14.5 |
| H29 | 0.0 | 0.0 | 28.1 | 8.5 | 0.2 | 3.2 | 0.0 | 9.1 | 13.2 | 1.2 |
| H30 | 0.0 | 18.3 | 21.8 | 13.6 | 0.2 | 2.5 | 0.0 | 12.5 | 7.2 | 4.6 |
| H31 | 0.0 | 12.4 | 27.4 | 15.8 | 0.1 | 2.8 | 24.2 | 0.0 | 0.0 | 3.9 |
| H32 | 0.0 | 15.2 | 21.7 | 11.3 | 0.1 | 2.3 | 0.0 | 18.7 | 0.0 | 11.6 |
| H33 | 0.0 | 12.7 | 20.8 | 12.5 | 0.0 | 1.1 | 1.3 | 13.2 | 0.0 | 8.5 |
| H34 | 0.0 | 14.6 | 31.2 | 0.0 | 0.0 | 0.0 | 0.0 | 21.3 | 0.0 | 3.5 |
| H35 | 0.0 | 7.3 | 22.5 | 9.8 | 0.0 | 2.1 | 0.0 | 18.6 | 0.0 | 2.1 |

| | | | | | | | | | Electrical characteristics | | |
|---|---|---|---|---|---|---|---|---|---|---|---|
| | | | | | | | | | (measured at 3 GHz) | | |
| | | | | | | | | | | | TCC |
| Sample | Fired low-temperature fired ceramic (wt %) | | | Fired glass component (mol %) | | | | | Relative | Q- | (ppm ° |
| No. | Ba [symbol] ZnTi [symbol] O [symbol] | CuO/Cu | Glass | BaO | ZnO | Al₂O₃ | B₂O₃ | SiO₂ | permittivity | factor | C.⁻¹) |
| H13 | 0.0 | 0.5 | 20.9 | 3.1 | 2.3 | 3.1 | 40.0 | 51.5 | 19.2 | 1580 | −25 |
| H14 | 10.3 | 0.0 | 23.2 | 1.5 | 3.5 | 2.5 | 41.3 | 51.2 | 18.3 | 1340 | 20 |
| H15 | 18.3 | 0.5 | 20.2 | 0.8 | 2.2 | 4.6 | 44.1 | 48.3 | 17.6 | 1210 | 33 |
| H16 | 7.6 | 1.0 | 21.1 | 3.6 | 2.1 | 5.3 | 38.7 | 50.3 | 17.3 | 1470 | −18 |
| H17 | 10.2 | 0.5 | 25.6 | 1.8 | 1.3 | 1.6 | 45.7 | 49.6 | 18.5 | 1780 | 6 |
| H18 | 5.3 | 0.5 | 27.7 | 6.8 | 5.3 | 1.2 | 38.2 | 48.5 | 20.3 | 2130 | −25 |
| H19 | 5.2 | 0.0 | 33.9 | 3.2 | 0.6 | 0.8 | 45.3 | 50.1 | 18.2 | 1150 | −8 |
| H20 | 0.0 | 0.5 | 32.8 | 3.8 | 6.2 | 0.7 | 42.1 | 47.2 | 17.4 | 1970 | −11 |
| H21 | 0.0 | 1.0 | 36.7 | 2.2 | 4.8 | 7.5 | 37.9 | 47.6 | 21.3 | 2290 | −3 |
| H22 | 2.5 | 0.0 | 34.4 | 6.3 | 3.5 | 4.8 | 37.8 | 47.6 | 18.9 | 1320 | −5 |
| H23 | 6.3 | 0.0 | 31.6 | 4.3 | 7.2 | 3.1 | 39.5 | 45.9 | 16.2 | 1080 | −14 |
| H24 | 12.7 | 0.0 | 19.3 | 3.1 | 5.4 | 4.9 | 41.2 | 45.4 | 17.9 | 1130 | −12 |
| H25 | 13.8 | 0.5 | 18.8 | 4.8 | 6.0 | 2.3 | 39.2 | 47.7 | 18.3 | 1250 | 25 |
| H26 | 4.2 | 0.5 | 12.1 | 5.2 | 3.2 | 5.1 | 38.1 | 48.4 | 22.1 | 2340 | −17 |
| H27 | 6.3 | 0.5 | 23.2 | 1.3 | 2.6 | 3.2 | 40.8 | 52.1 | 20.8 | 1950 | 5 |
| H28 | 4.7 | 0.5 | 14.7 | 0.5 | 2.6 | 3.2 | 42.3 | 51.4 | 20.5 | 2170 | −10 |
| H29 | 18.8 | 1.0 | 16.7 | 0.6 | 3.8 | 2.5 | 43.7 | 49.4 | 21.5 | 2080 | −28 |
| H30 | 0.0 | 1.0 | 18.3 | 3.2 | 0.5 | 3.2 | 41.8 | 51.3 | 20.3 | 1430 | −20 |
| H31 | 0.0 | 0.8 | 12.6 | 4.3 | 1.8 | 2.5 | 40.3 | 51.1 | 23.3 | 2250 | −25 |
| H32 | 2.5 | 0.8 | 15.8 | 1.3 | 3.3 | 2.8 | 40.9 | 51.7 | 22.3 | 1630 | −23 |
| H33 | 0.0 | 0.5 | 29.4 | 4.8 | 3.3 | 5.2 | 38.3 | 48.4 | 13.8 | 1310 | 35 |
| H34 | 9. [symbol] | 0.5 | 19.1 | 3.1 | 5.2 | 4.9 | 39.7 | 47.1 | 16.7 | 1520 | 73 |
| H35 | 15.9 | 0.0 | 21.7 | 6.3 | 4.2 | 5.1 | 36.8 | 47.6 | 12.6 | 820 | −21 |

[symbol]

indicates data missing or illegible when filed

The fired low-temperature fired ceramics of sample Nos. H13 to H34 each corresponded to the second low-temperature fired ceramic of the present disclosure, because the percentage of BaO (percentage of RO), the percentage of ZnO, and the percentage of Al₂O₃ in the fired glass component were each 0.1 mol % to 10 mol %, the sum of the percentage of BaO (percentage of RO), the percentage of ZnO, and the percentage of Al₂O₃ in the fired glass component was 15 mol % or less, and the oxides of the ceramic crystalline components (C2) included at least one selected from the group consisting of Ba₂Ti₉O₂₀, BaTi(BO₃)₂, BaTi₄O₉, BaTi₅O₁₁, Ba₄Ti₁₃O₃₀, BaZn₂Ti₄O₁, and Ba₄ZnTin₁₁O₂₇.

Each of these samples had a high Q-factor, indicating a low-temperature fired ceramic with a small dielectric loss. Sample Nos. H13 to H33 each had a TCC in the range of −25 ppm ° C.⁻¹ to 35 ppm ° C.⁻¹, indicating an extremely low temperature dependence of relative permittivity. Each of the samples also had a high relative permittivity.

Sample No. H33 had a slightly low relative permittivity and a relatively high TCC because the percentage of the barium titanate compounds, which were oxides of ceramic crystalline components, was less than 40 wt %. Sample No. H34 had a slightly high TCC of 73 ppm ° C.⁻¹ because it contained only one oxide of a ceramic crystalline component, BaAl₂Si₂O₈, other than the barium titanate compounds. Sample No. H35 had a low Q-factor because the sum of the percentage of RO, the percentage of ZnO, and the percentage of Al₂O₃ in the fired glass component was more than 15 mol %.

### Production of Electronic Components Including Low-Permittivity Ceramic Layers and High-Permittivity Ceramic Layers 2

The samples for evaluating sinterability were produced as follows. The low-permittivity green sheets and high-permittivity green sheets produced above were cut into 50-mm square pieces. In each of the combinations shown in Table 8, eight pieces of the low-permittivity green sheet, four pieces of the high-permittivity green sheet, and eight pieces of the low-permittivity green sheet were stacked in sequence, placed in a mold, and compression-bonded using a pressing machine. The compression-bonded body was fired in a reducing atmosphere at a temperature of 900° C. or higher and 950° C. or lower for 60 minutes, whereby a fired body was obtained.

The fired body was embedded in resin, followed by curing. The cross section was polished and examined with a scanning electron microscope (SEM) for the presence or absence of defects such as delamination, pores, or cracks at the boundaries between the ceramic layers with different relative permittivities.

The composition of the glass in the fired body was determined as follows: a glass area of an exfoliated sample was identified using a scanning transmission electron microscope (STEM) and electron diffraction, and the glass area was analyzed by wavelength dispersive X-ray analysis (WDS) to determine the composition of the glass. The crystal species and crystal contents in the ceramic layers with low permittivity in the fired body were determined by performing XRD on the surface of the fired body sample. The crystal species and crystal contents in the ceramic layers with high permittivity were determined by polishing away the low permittivity portion from the surface of the fired body sample to expose the layer with high permittivity, and performing XRD on the exposed surface.

Table 8 shows the presence or absence of defects at the boundaries between the ceramic layers with different relative permittivities.

TABLE 8

| | High- | Low- | |
|---|---|---|---|
| | permittivity | permittivity | |
| Sample No. | layer | layer | Boundary state |
| E6 | H18 | L14 | No defects |
| E7 | H18 | L16 | Delamination |
| E8 | H26 | L17 | Pores, cracks |
| E9 | H30 | L14 | No defects |
| E10 | H30 | L17 | Pores, cracks |
| E11 | H30 | L18 | No defects |

The electronic components of sample Nos. E6, E9, and E11 each corresponded to an electronic component of the present disclosure because both the low-permittivity ceramic layers and the high-permittivity ceramic layers contained low-temperature fired ceramics of the present disclosure.

In the electronic components of sample Nos. E6, E9, and E11, no defects were found at the boundaries between the low-permittivity ceramic layers and the high-permittivity ceramic layers. In sample No. E7, the low-permittivity ceramic sample No. L16 contained no BaAl₂Si₂O₈, and therefore delamination was observed at the boundaries between the low-permittivity ceramic layers and the high-permittivity ceramic layers when the low-permittivity ceramic was co-sintered with the high-permittivity ceramic. In sample No. E8 and E10, the low-permittivity ceramic sample No. L17 contained more than 5 wt % of Al₂O₃, and therefore pores or cracks were observed at the boundaries between the low-permittivity ceramic layers and the high-permittivity ceramic layers when the low-permittivity ceramic was co-sintered with the high-permittivity ceramic.

The results show that some compositions of the low-temperature fired ceramics of the present disclosure may result in delamination, pores, or cracks at the boundaries between the low-permittivity ceramic layers and the high-permittivity ceramic layers upon co-sintering, even if the compositions cause no problems when used in an electronic component without co-sintering of the low-permittivity ceramic and the high-permittivity ceramic.

### REFERENCE SIGNS LIST

1, 100 laminate
2, 200 electronic component
3 low-temperature fired ceramic layer
4 low-permittivity ceramic layer
5 high-permittivity ceramic layer
9, 10, 11 conductive layer
12 via hole conductive layer
13, 14 chip component
21, 110 multilayer green sheet
22 green sheet
23 low-permittivity ceramic layer green sheet
24 high-permittivity ceramic layer green sheet

1. A low-temperature fired ceramic comprising:
a fired glass component represented by RO—ZnO—Al₂O₃—B₂O₃—SiO₂, wherein
RO is at least one selected from the group consisting of MgO, CaO, SrO, and BaO,
a percentage of RO, a percentage of ZnO, and a percentage of Al₂O₃ in the fired glass component are each 0.1 mol % to 10 mol %,
a sum of the percentage of RO, the percentage of ZnO, and the percentage of Al₂O₃ in the fired glass component is 15 mol % or less, and
a ratio of a percentage of SiO₂ to a percentage of B₂O₃(SiO₂/B₂O₃) in the fired glass component is less than 3.4; and
one or more oxides of ceramic crystalline components that include at least one selected from the group consisting of SiO₂, BaAl₂Si₂O₈, ZnAl₂O₄, and Zn₂SiO₄.

2. The low-temperature fired ceramic according to claim 1, wherein the one or more oxides of the ceramic crystalline components further include TiO₂.

3. The low-temperature fired ceramic according to claim 1, wherein the one or more oxides of the ceramic crystalline components include BaAl₂Si₂O₈ and at least two selected from the group consisting of SiO₂, ZnAl₂O₄, Zn₂SiO₄, and TiO₂.

4. The low-temperature fired ceramic according to claim 1, wherein a percentage of BaAl₂Si₂O₈ in the low-temperature fired ceramic is more than 0 wt % and 5 wt % or less.

5. The low-temperature fired ceramic according to claim 1, wherein the low-temperature fired ceramic further comprises Al₂O₃ in addition to the Al₂O₃ contained in the fired glass component, and a percentage of Al₂O₃ in the low-temperature fired ceramic, excluding the Al₂O₃ contained in the fired glass component, is more than 0 wt % and 5 wt % or less.

6. The low-temperature fired ceramic according to claim 1, wherein RO is BaO.

7. The low-temperature fired ceramic according to claim 1, wherein the low-temperature fired ceramic further comprises CuO and/or Cu, and a sum of a percentage of the CuO and a percentage of the Cu in the low-temperature fired ceramic is 1 wt % or less.

8. An electronic component comprising the low-temperature fired ceramic according to claim 1.

9. The electronic component according to claim 8, wherein the electronic component includes Cu wiring.

10. A low-temperature fired ceramic comprising:
a fired glass component represented by RO—ZnO—Al₂O₃—B₂O₃—SiO₂, wherein
RO is at least one selected from the group consisting of MgO, CaO, SrO, and BaO,
a percentage of RO, a percentage of ZnO, and a percentage of Al₂O₃ in the fired glass component are each 0.1 mol % to 10 mol %, and
a sum of the percentage of RO, the percentage of ZnO, and the percentage of Al₂O₃ in the fired glass component is 15 mol % or less, and
one or more oxides of ceramic crystalline components that include at least one selected from the group consisting of Ba₂Ti₉O₂₀, BaTi(BO₃)₂, BaTi₄O₉, BaTi₅O₁₁, Ba₄Ti₁₃O₃₀, BaZn₂Ti₄O₁₁, and Ba₄ZnTi₁₁O₂₇.

11. The low-temperature fired ceramic according to claim 10, wherein a sum of a percentage of the Ba₂Ti₉O₂₀ and a percentage of the BaTi(BO₃)₂ in the low-temperature fired ceramic is 40 wt % or more.

12. The low-temperature fired ceramic according to claim 10, wherein a sum of a percentage of the Ba₂Ti₉O₂₀, a percentage of the BaTi(BO₃)₂, a percentage of the BaTi₄O₉, a percentage of the BaTi₅O₁₁, a percentage of the Ba₄Ti₁₃O₃₀, a percentage of the BaZn₂Ti₄O₁₁, and a percentage of the Ba₄ZnTi₁₁O₂₇ in the low-temperature fired ceramic is 40 wt % or more.

13. The low-temperature fired ceramic according to claim 10, wherein the one or more oxides of the ceramic crystalline components further include at least two selected from the group consisting of TiO₂, BaAl₂Si₂O₈, ZnAl₂O₄, and Zn₂SiO₄.

14. The low-temperature fired ceramic according to claim 13, wherein the one or more oxides of the ceramic crystalline components include TiO₂ and at least one selected from the group consisting of BaAl₂Si₂O₈, ZnAl₂O₄, and Zn₂SiO₄.

15. The low-temperature fired ceramic according to claim 10, wherein RO is BaO.

16. The low-temperature fired ceramic according to claim 10, wherein the low-temperature fired ceramic further comprises CuO and/or Cu, and a sum of a percentage of the CuO and a percentage of the Cu in the low-temperature fired ceramic is 1 wt % or less.

17. An electronic component comprising the low-temperature fired ceramic according to claim 10.

18. The electronic component according to claim 17, wherein the electronic component includes Cu wiring.

19. An electronic component comprising:
a low-permittivity ceramic layer containing a first low-temperature fired ceramic; and
a high-permittivity ceramic layer containing a second low-temperature fired ceramic, the high-permittivity ceramic layer having a permittivity greater than the low-permittivity ceramic layer, wherein
the first low-temperature fired ceramic contains a first fired glass component and one or more first oxides of ceramic crystalline components,
the second low-temperature fired ceramic contains a second fired glass component and one or more second oxides of ceramic crystalline components,
the first fired glass component and the second fired glass component are represented by RO—ZnO—Al₂O₃—B₂O₃—SiO₂,
RO is at least one selected from the group consisting of MgO, CaO, SrO, and BaO,
a percentage of RO, a percentage of ZnO, and a percentage of Al₂O₃ in the first fired glass component and a percentage of RO, a percentage of ZnO, and a percentage of Al₂O₃ in the second fired glass component are each 0.1 mol % to 10 mol %, and
a sum of the percentage of RO, the percentage of ZnO, and the percentage of Al₂O₃ in the first fired glass component and a sum of the percentage of RO, the percentage of ZnO, and the percentage of Al₂O₃ in the second fired glass component are each 15 mol % or less,
a ratio of a percentage of SiO₂ to a percentage of B₂O₃(SiO₂/B₂O₃) in the first fired glass component is less than 3.4,
the first low-temperature fired ceramic further comprises Al₂O₃ in addition to the Al₂O₃ contained in the first fired glass component, and a percentage of the Al₂O₃ in the first low-temperature fired ceramic, excluding the Al₂O₃ contained in the first fired glass component, is more than 0 wt % and 5 wt % or less,
the one or more first oxides of the ceramic crystalline components include BaAl₂Si₂O₈ and at least two selected from the group consisting of SiO₂, ZnAl₂O₄, Zn₂SiO₄, and TiO₂,
a percentage of BaAl₂Si₂O₈ in the first low-temperature fired ceramic is more than 0 wt % and 5 wt % or less, and
the one or more second oxides of the ceramic crystalline components include at least one selected from the group consisting of Ba₂Ti₉O₂₀, BaTi(BO₃)₂, BaTi₄O₉, BaTi₅O₁₁, Ba₄Ti₁₃O₃₀, BaZn₂Ti₄O₁₁, and Ba₄ZnTi₁₁O₂₇.

20. The electronic component according to claim 19, wherein the electronic component includes Cu wiring.
